(19) United States
(12) Patent Application Publication
(10) Pub. No.: US 2024/0333282 A1
(43) Pub. Date: Oct. 3, 2024

(54) SMART DIMMER SYSTEM HAVING IMPROVED RELIABLE COMMUNICATION

(71) Applicant: FEIT ELECTRIC COMPANY, INC., Pico Rivera, CA (US)

(72) Inventors: Hu Sanhong, Shenzhen (CN); Zhu Wei, Huizhou (CN); Li Changqing, Shenzhen (CN); Ye Jiansheng, Beijing (CN)

(21) Appl. No.: 18/501,877

(22) Filed: Nov. 3, 2023

Related U.S. Application Data
(63) Continuation of application No. 17/901,254, filed on Sep. 1, 2022, now abandoned.
Application No. 17/901,254 is a continuation of application No. 16/875,720, filed on May 15, 2020.

(30) Foreign Application Priority Data
May 16, 2019 (CN) 201920699204.7

(51) Int. Cl. H03K 17/62; H01H 13/70; H01H 23/00; H01H 23/24; H03K 17/51; H03K 17/74; H03K 17/965; H05B 45/10; H05B 47/19

(52) U.S. Cl. CPC H03K 17/6207; H01H 13/7013; H01H 23/003; H01H 23/24; H03K 17/74; H03K 17/965; H03K 2017/515; H05B 45/10; H05B 47/19

(57) ABSTRACT

Systems, methods, and apparatuses are provided for a single or multi-dimmer system having improved reliable connectivity between a dimmer assembly and a switch or between two or more dimmer assemblies.

### CROSS-REFERENCE TO RELATED APPLICATIONS

The present application is a continuation of U.S. application Ser. No. 17/901,254, titled “Smart Dimmer System Having Improved Reliable Communication,” filed Sep. 1, 2022, which is a continuation of U.S. application Ser. No. 16/875,720, titled “Smart Dimmer System Having Improved Reliable Communication,” filed May 15, 2020, which claims priority to Chinese Patent Application No. 201920699204.7, titled “A new type of single line communication control smart dimmer switch,” filed May 16, 2019, the contents of which are incorporated herein by reference in their entirety.

### BACKGROUND

Dimmers are devices connected to a light fixture and used to lower the brightness of light. By changing the voltage waveform applied to the lamp, it is possible to lower the intensity of the light output. In recent years, “smart dimmers” have become available, however they come with strict wiring requirements. For example, existing smart dimmers require that a “neutral” line be available for connection. Those existing smart dimmers that do not require a “neutral” line are not compatible with LED or other conventional lighting (i.e., they may only work with incandescent lighting). Further, existing smart dimmers are not compatible with standard three-way switches (i.e., they require specialized switches). These and other complications make existing smart dimmers an unattractive solution to those users who do not want to re-wire an entire structure and/or replace existing three-way switches.

Through applied effort, ingenuity, and innovation many deficiencies of such systems have been solved by developing solutions that are in accordance with the embodiments of the present invention, many examples of which are described in detail herein.

### SUMMARY

Embodiments of the present disclosure provide a single-line half-duplex communication intelligent dimmer assembly. Internal circuitry of the dimmer assembly includes an asynchronous transceiver (referred to herein as “UART”) for asynchronous communication (e.g., half-duplex transmission and reception) between a first dimmer assembly and a second dimmer assembly, or between a first dimmer assembly and a traditional/standard three-way switch.

In embodiments, a multi-dimmer system, comprises a first dimmer assembly electrically coupled to a second dimmer assembly via a physical data transmission line. In embodiments, the first dimmer assembly receives dimming instructions via one or more of a first actuatable physical switch or a communications module in communication with one or more remote computing devices. In embodiments, the first dimmer assembly acts as a master device and the second dimmer assembly acts as a slave device such that dimming instructions carried out by the first dimmer assembly are propagated via the data transmission line to the second dimmer assembly.

In embodiments, the physical data transmission line is a single electrical wire.

In embodiments, the first dimmer assembly is electrically couplable to a “hot” line of a voltage source, and ground.

In embodiments, the first dimmer assembly is also electrically couplable to a “neutral” line of the voltage source.

In embodiments, an output of the first dimmer assembly remains floating.

In embodiments, the second dimmer assembly is electrically couplable with a “hot” line of a voltage source, a lighting or other load, and ground. In embodiments, the second dimmer assembly is electrically couplable with the lighting or other load via an output of the second dimmer assembly.

In embodiments, the lighting or other load is electrically couplable with a “neutral” line of the voltage source.

In embodiments, each of the first dimmer assembly and the second dimmer assembly comprises an MCU, a communication circuit, and a communications module.

In embodiments, the communication circuit comprises a transmission port TX_B coupled to an MCU data transmission port. In embodiments, the communication circuit comprises a receiving port RX_B coupled to an MCU data receiving port.

In embodiments, a waveform of the data transmission line follows a signal waveform of the transmission port TX_B.

In embodiments, when a TX_B of the first dimmer assembly transmits data, a TX_B of the second dimmer assembly does not transmit data.

In embodiments, when the TX_B of the second dimmer assembly transmits data, the TX B of the first dimmer assembly does not transmit data.

In embodiments, the communications module enables communication via a wireless communications network with a remote computing device.

In embodiments, a multi-dimmer system further comprises a third dimmer assembly electrically coupled a fourth dimmer assembly via a second physical data transmission line. In embodiments, the third dimmer assembly receives dimming instructions via one or more of the first actuatable physical switch, a second actuatable physical switch, or a second communications module in communication with one or more remote computing devices.

In embodiments, the third dimmer assembly acts as a master device and the fourth dimmer assembly acts as a slave device such that dimming instructions carried out by the third dimmer assembly are propagated via the second data transmission line to the fourth dimmer assembly.

In embodiments, a dimmer system comprises a first dimmer assembly electrically coupled to a standard three-way switch via a physical data transmission line. In embodiments, the first dimmer assembly receives dimming instructions via one or more of an actuatable physical switch or a communications module in communication with a remote computing device. In embodiments, instructions carried out by the first dimmer assembly are propagated via the data transmission line to the standard three-way switch.

This Summary does not attempt to completely signify any particular innovation, embodiment, or example as it can be used in commerce. Additionally, this Summary is not intended to signify essential elements of an innovation, embodiment or example or to limit the scope of the subject matter of this disclosure.

The innovations, embodiments, and/or examples found within this disclosure are not all-inclusive, but rather describe the basic significance of the subject matter. Accordingly, one use of this Summary is as a prelude to a Detailed Description presented later.

### BRIEF DESCRIPTION OF THE DRAWINGS

The following Detailed Description, Figures, and appended Claims signify the nature and advantages of the innovations, embodiments and/or examples of the claimed inventions. All of the Figures signify innovations, embodiments, and/or examples of the claimed inventions for purposes of illustration only and do not limit the scope of the claimed inventions. Such Figures are not necessarily drawn to scale, and are part of the Disclosure.

In the Figures, similar components or features may have the same, or similar, reference signs in the form of labels (such as alphanumeric symbols, e.g., reference numerals), and may signify similar or equivalent functionality. Further, various components of the same type may be distinguished by following the reference label by a dash and a second label that distinguishes among the similar components. If only the first reference label is used in the specification, the description is applicable to any one of the similar components having the same first reference label irrespective of the second reference label. A brief description of the Figures is below.

FIG. 1 illustrates a prior art three-way switch system;

FIG. 2A illustrates an exemplary communication circuit for use with embodiments of the present disclosure;

FIG. 2B illustrates an exemplary single-line communication circuit transmission signal map for use with embodiments of the present disclosure;

FIG. 2C illustrates an exemplary single-line communication circuit signal receiving map for use with embodiments of the present disclosure;

FIG. 3A illustrates an exemplary dimmer system according to embodiments of the present disclosure;

FIG. 3B illustrates an exemplary dimmer system according to embodiments of the present disclosure;

FIG. 3C illustrates an exemplary dimmer system according to embodiments of the present disclosure;

FIG. 4A illustrates an exemplary multi-dimmer system according to embodiments of the present disclosure;

FIG. 4B illustrates an exemplary multi-dimmer system according to embodiments of the present disclosure;

FIG. 4C illustrates an exemplary multi-dimmer system according to embodiments of the present disclosure;

FIG. 5A illustrates a front view of an exemplary dimmer assembly for use with embodiments of the present disclosure;

FIG. 5B illustrates a front view of an exemplary dimmer assembly for use with embodiments of the present disclosure;

FIG. 5C illustrates a front view of an exemplary dimmer assembly for use with embodiments of the present disclosure;

FIG. 6A illustrates a rear view of an exemplary dimmer assembly for use with embodiments of the present disclosure;

FIG. 6B illustrates a rear view of an exemplary dimmer assembly for use with embodiments of the present disclosure;

FIG. 7 illustrates an exploded view of an exemplary dimmer assembly for use with embodiments of the present disclosure;

FIG. 8 illustrates an exemplary system architecture for use with embodiments of the present disclosure; and

FIG. 9 illustrates an apparatus for use with embodiments of the present disclosure.

In such various figures, reference signs may be omitted as is consistent with accepted engineering practice; however, one of ordinary skill in the art will understand that the illustrated components are readily understood when viewed in context of the illustration as a whole and the accompanying disclosure describing such various figures.

### DETAILED DESCRIPTION

The Figures and the following Detailed Description signify innovations, embodiments and/or examples by way of illustration only, with various features, structures or characteristics described together in a single embodiment to streamline the disclosure. Variations of any of the elements, processes, machines, systems, manufactures or compositions disclosed by such exemplary innovations, embodiments and/or examples will be readily recognized and may be used in commerce without departing from the principles of what is claimed. The Figures and Detailed Description may also signify, implicitly or explicitly, advantages and improvements of a subset of the exemplary embodiments described herein.

In the Figures and Detailed Description, numerous specific details may be described to enable one or more of the exemplary innovations, embodiments and/or examples. In the interest of not obscuring the presentation of the exemplary innovations, embodiments and/or examples in the following Detailed Description, some processing steps or operations that are known in the art may be combined together for presentation and for illustration purposes and might not be described in detail. However, a person skilled in the art will recognize that these exemplary innovations, embodiments and/or examples may be used in commerce without these specific details or with equivalents thereof. In other instances, well-known processes and devices are not described in detail as not to unnecessarily obscure aspects of these exemplary innovations, embodiments and/or examples. In other instances, some processing steps or operations that are known in the art may not be described at all. Instead, the following description is focused on the distinctive features or elements of various exemplary innovations, embodiments and/or examples. Furthermore, while this description may refer to some components of the structure in the singular tense, more than one component may be depicted throughout the Figures and like components are labeled with like numerals.

Embodiments of the present disclosure provide a single-line half-duplex communication intelligent dimmer assembly. Internal circuitry of the dimmer assembly includes an asynchronous transceiver (referred to herein as “UART”) for asynchronous communication (e.g., half-duplex transmission and reception) between a first dimmer assembly and a second dimmer assembly, or between a first dimmer assembly and a traditional/standard three-way switch.

In exemplary embodiments of dimmer systems herein, a dimmer switch/assembly can easily be connected to a standard three-way switch without additional wiring or equipment.

Embodiments of the present disclosure enable mutual control of multiple dimmer switches/assemblies that are installed in different places because each dimmer switch/assembly may act as a master or a slave. The electrical connection between the coupled dimmer switch/assemblies is reliable as it is a fixed or wired connection, eliminating communication interruption issues associated with existing wireless protocols (e.g., Bluetooth, WiFi, and the like). Electrically coupling multiple dimmer switch/assemblies to one another while also providing remote control of the assemblies via a wireless communication module makes operation of the system more convenient for a remote computing device because the computing device need only transmit a single set of instructions to a single dimmer switch/assembly which can be designated a master and instruct any slave dimmer switch/assembly.

The embodiments described herein provide improvements over existing smart or intelligent dimmers because they do not require additional or altered wiring in existing structures. The embodiments described herein further provide improvements over existing solutions because the dimmer assembly can be used with a traditional or standard three-way switch, eliminating a need for additional equipment or circuitry.

In exemplary embodiments of multi-dimmer systems herein, two dimmer switches/assemblies have identical communication circuits and a shared communication line (e.g., A (UART)). The two dimmer switch/assemblies can communicate with each other such that when one dimmer is “dimmed,” the second dimmer can follow dimming. Each dimmer switch/assembly comprises a wireless communication module for access by a computing device. That is, a computing device may wirelessly control the dimmer switch/assembly by transmitting instructions to the wireless communication module. The wireless communication module provides the instructions to an MCU (i.e., master control unit) for translation and processing, and the MCU controls the communication circuit using signals based on the instructions received from a computing device.

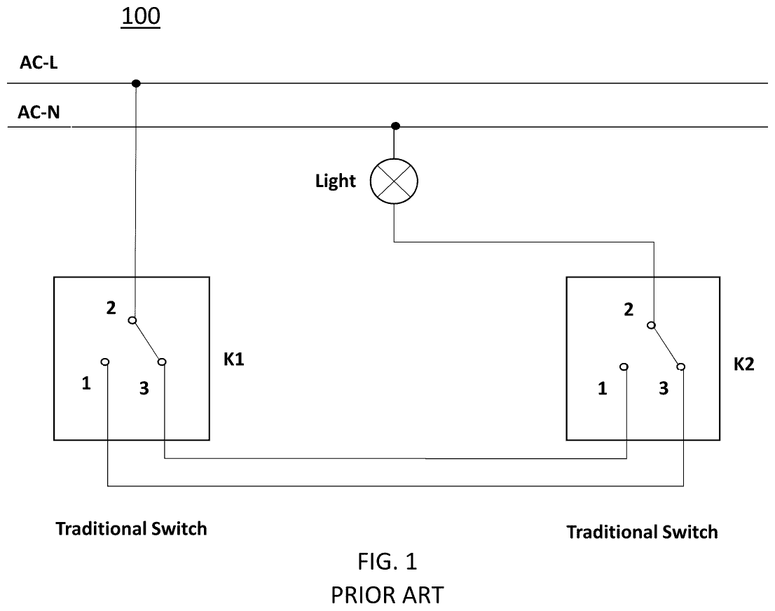

FIG. 1 illustrates a prior art three-way switch system 100. In the prior art system 100, two three-way switches (K1, K2) are connected between an AC voltage source (AC-L, AC-N) and a lighting load (“Light”). The three-way switches (K1, K2) each include movable (or common) contacts (e.g., contact 2 in each switch), which are electrically connected to the AC voltage source (AC-L) and the lighting load (“Light”) respectively. That is, contact 2 of switch K1 is connected to AC-L; contact 2 of switch K2 is connected to the lighting load (“Load”).

In FIG. 1, the three-way switches (K1, K2) each also include two fixed contacts (e.g., contacts 1 and 3 in each switch). When the movable contacts are making contact with a first fixed contact (e.g., contact 1 in each switch in FIG. 1), the three-way switches are in position 1. When the movable contacts are making contact with a second fixed contact (e.g., contact 3 in each switch in FIG. 1), the three-way switches are in position 3.

When the three-way switches K1, K2 are both in position 1 or are both in position 3, the circuit of system 100 is complete and the lighting load (“Light”) is energized. When switch K1 is in position 1 and switch K2 is in position 3, or vice versa, the circuit of system 100 is not complete and the lighting load (“Light”) is not energized.

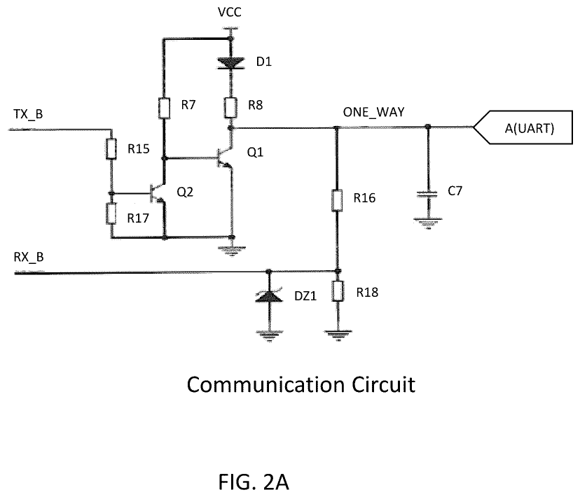

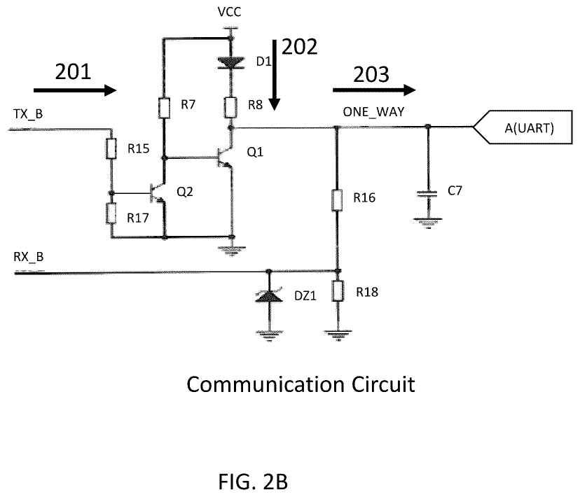

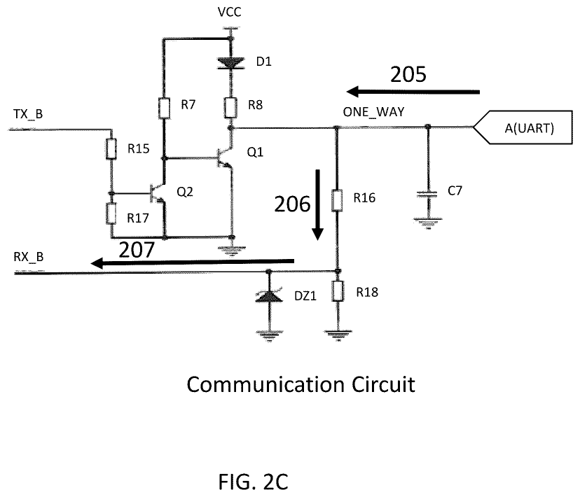

FIG. 2A illustrates an exemplary communication circuit for use with embodiments of the present disclosure. FIG. 2B illustrates an exemplary single-line communication circuit transmission signal map for use with embodiments of the present disclosure. FIG. 2C illustrates an exemplary single-line communication circuit signal receiving map for use with embodiments of the present disclosure.

Referring to FIG. 2A, TX_B corresponds to an MCU data transmission port, RX_B corresponds to the MCU receiving port, and A (UART) is a data/communication line.

Referring to FIG. 2B, a signal is transmitted along a path 201, which results in TX_B being a 1 or 0 level pulse waveform.

If a high signal is transmitted along path 201, TX_B divides by R15 and R17 to reach Q2 and cause a turn on condition for Q2. After Q2 turns on, a CE pole saturation voltage drop of Q2 (e.g., of 0.2V) will pull Q1's B pole low. After the B pole of Q1 is less than a particular voltage level (e.g., 0.7V), it is cut off from the on state. At this time, VCC transmits a high level signal along a path 202/203 to A (UART) through D1 and R8.

If a low signal is transmitted along path 201, the B pole of Q2 receives no voltage and therefore is cut off from the on state. At this time, VCC can turn on Q1 through R7. A (UART) is equivalent to ground, which is low level. Because of the resistance caused by D1 and R8 on the voltage of VCC, the voltage is equivalent to the VCC to ground load. Accordingly, VCC is not affected.

In summary, when a signal is transmitted along TX_B, it is inverted by Q2 and then inverted by Q1, so the A (UART) waveform can follow the TX_B signal waveform and can be synchronized.

Referring to FIG. 2C, it can be seen that the circuit can distinguish between data transmitted via TX_B and that received via A (UART) due to separate loops. For example, a receiving loop comprises paths 205, 206, 207 of FIG. 2C; that is, the receiving loop 205/206/207 is associated with externally transmitted data via A (UART) while another receiving loop may be associated with data transmitted via TX_B.

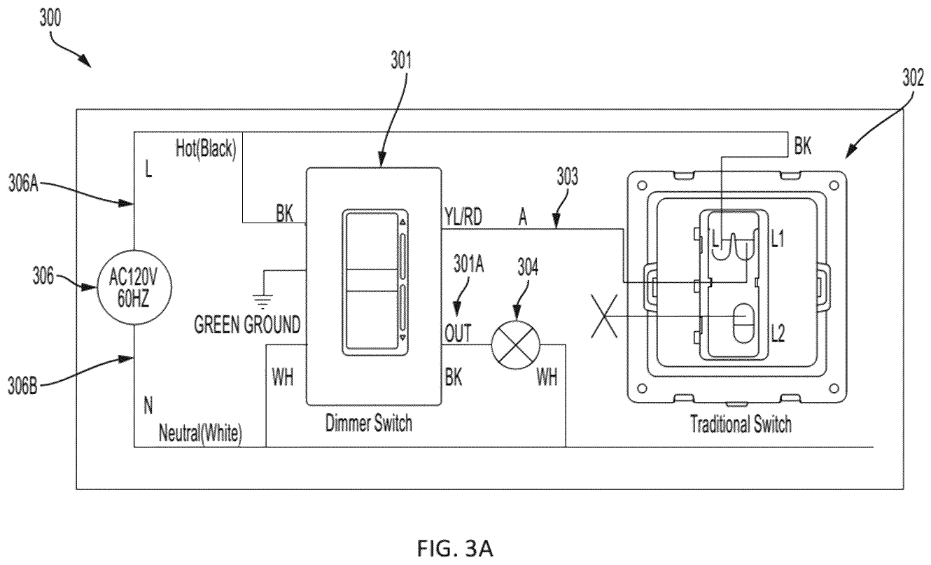

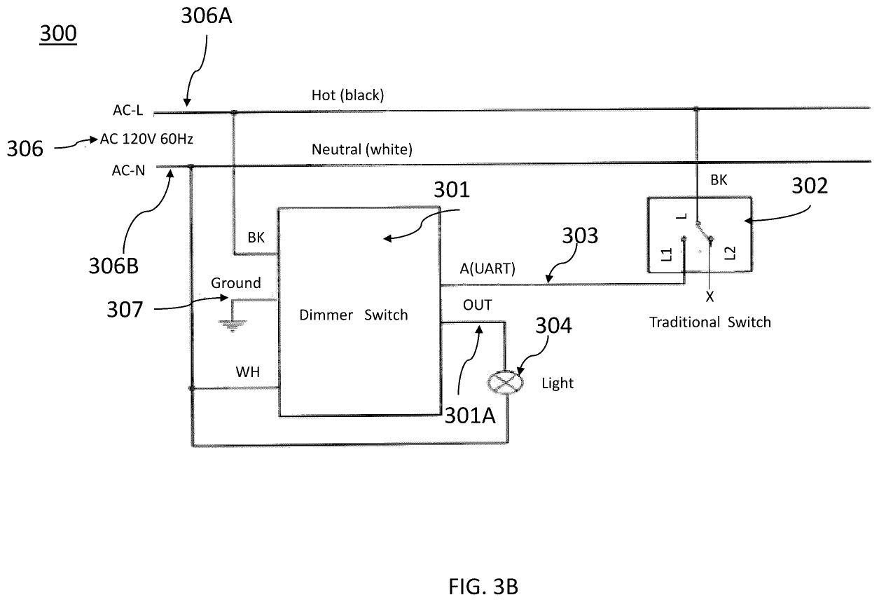

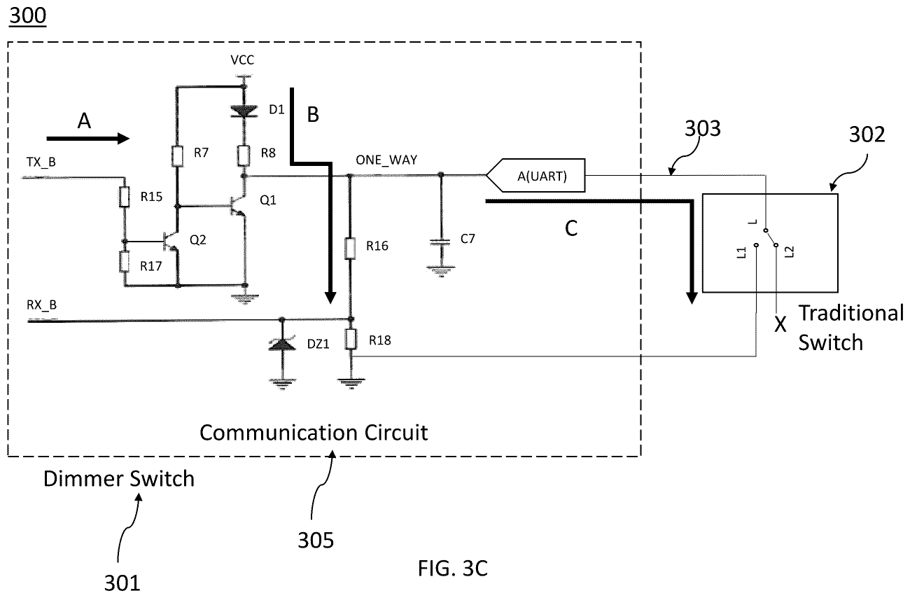

FIGS. 3A-3B illustrate an exemplary dimmer system 300 according to embodiments of the present disclosure. In embodiments, an exemplary dimmer system 300 comprises a dimmer switch/assembly 301 as described herein and the dimmer switch/assembly 301 is electrically coupled with a traditional switch 302. The dimmer/switch assembly 301 communicates with the traditional switch 302 via a data transmission line A 303 (also referred to herein as “A (UART)”). The dimmer switch/assembly 301 controls voltage provided to a lighting or other load 304, as the lighting or other load 304 is electrically coupled to an output 301A of the dimmer switch/assembly 301. The lighting or other load 304 is also electrically coupled with a “neutral” line 306B from voltage source 306.

The dimmer switch/assembly 301 is electrically coupled between a “hot” line 306A from voltage source 306 (e.g., AC 120V, 60 Hz) and a “neutral” line 306B from voltage source 306. The dimmer switch/assembly 301 is also electrically coupled to ground 307.

In embodiments, traditional switch 302 is electrically coupled (e.g., at connection “L”) to the “hot” line 306A of voltage source 306 in addition to the data transmission line A 303 (e.g., at connection “L1”). It will be appreciated that a connection (e.g., “L2”) of traditional switch 302 remains unused or floating.

In applications of the exemplary dimmer system 300, existing wiring (e.g., black, white, green, etc. as shown in FIGS. 3A-3B) can be utilized to electrically couple dimmer switch/assembly 301 to a voltage source 306 and a lighting or other load 304.

FIG. 3C illustrates an exemplary signal transmission within an exemplary dimmer system 300 according to embodiments of the present disclosure. In embodiments, dimmer switch/assembly 301 comprises a communication circuit 305 that is electrically coupled to traditional switch 302 by way of data transmission line A (UART) and to ground. It will be appreciated that TX_B and RX_B are electrically coupled to an MCU (not shown).

In embodiments, when a signal is transmitted on TX_B, it may be the result of the MCU (not shown) program forcing the I/O port (e.g., TX_B) to a high level. When this happens, RX_B detects a switch status change and receives a signal. When the traditional switch 302 is turned on (i.e., L to L1 is closed), it is equivalent to A (UART) to ground. When the traditional switch 302 is turned off (i.e., L to L2 is closed), the equivalent of A (UART) is a floating state. Accordingly, when TX_B is used as a normal I/O port, an MCU pull-up resistor allows TX_B to output a high level.

In embodiments, when TX_B outputs a high level (i.e., voltage level high or “hot”) along path A of FIG. 3C, after R15 and R17 divide the voltage, Q2 is turned on and Q1 is turned off. Subsequently, along a path B in FIG. 3C, a VCC signal passes through D1 and R8 to A (UART), and then is divided by an upper bias resistor R16 and a lower bias resistor R18 to reach a Zener diode DZ1. After the voltage signal is stabilized, it enters the MCU receiving pin RX_B. At this time, if the traditional switch 302 is in an off state (i.e., L to L2 is closed), RX B will detect the high level. If the detected high level continues and does not change for a particular duration of time (e.g., 300 ms), the MCU determines that the switch is not in operation. Otherwise, if the traditional switch 302 is closed on in an on state (i.e., L to L1 is closed), a signal is passed along a path C such that A (UART) is connected to ground. RX_B is then forced to a low level. If the detected low level on RX_B continues for a particular duration of time (e.g., 300 ms), the MCU determines that the switch is in operation and requires an action. The MCU then performs the corresponding action of turning the dimmer switch on or off.

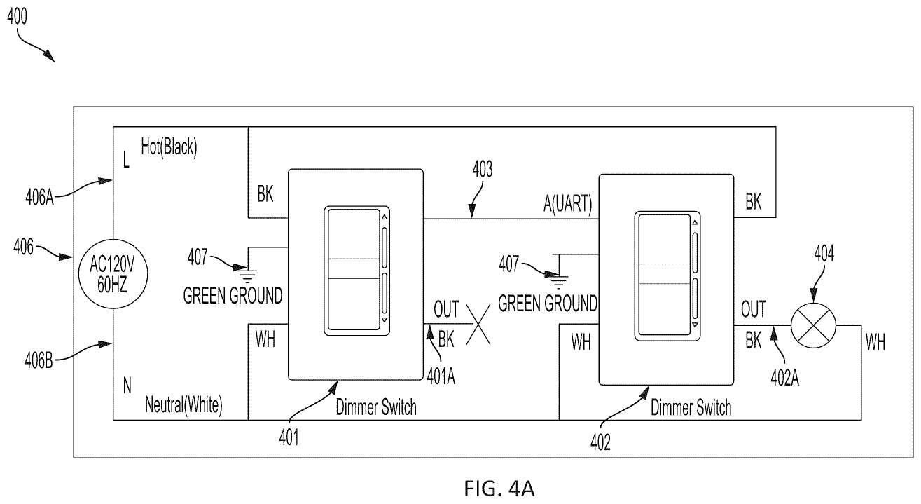

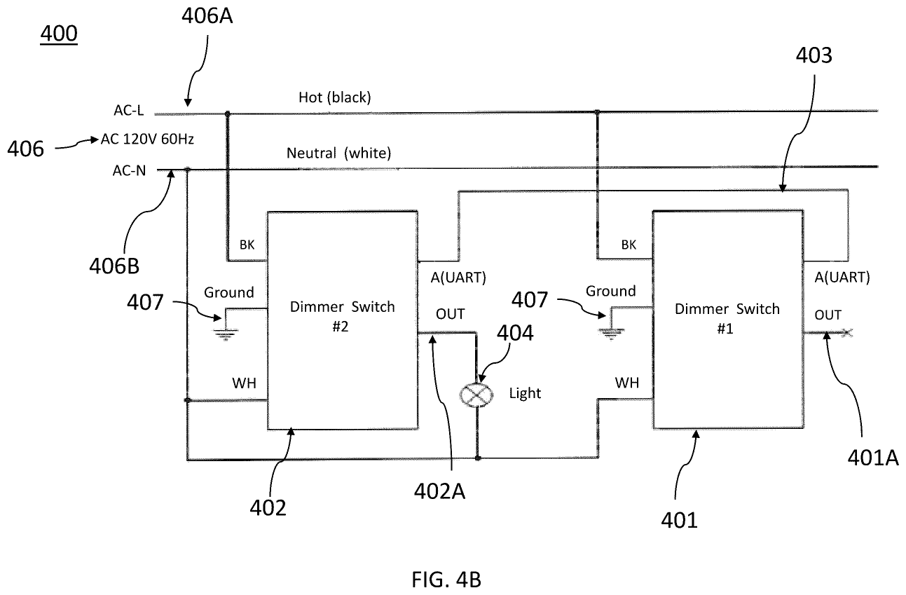

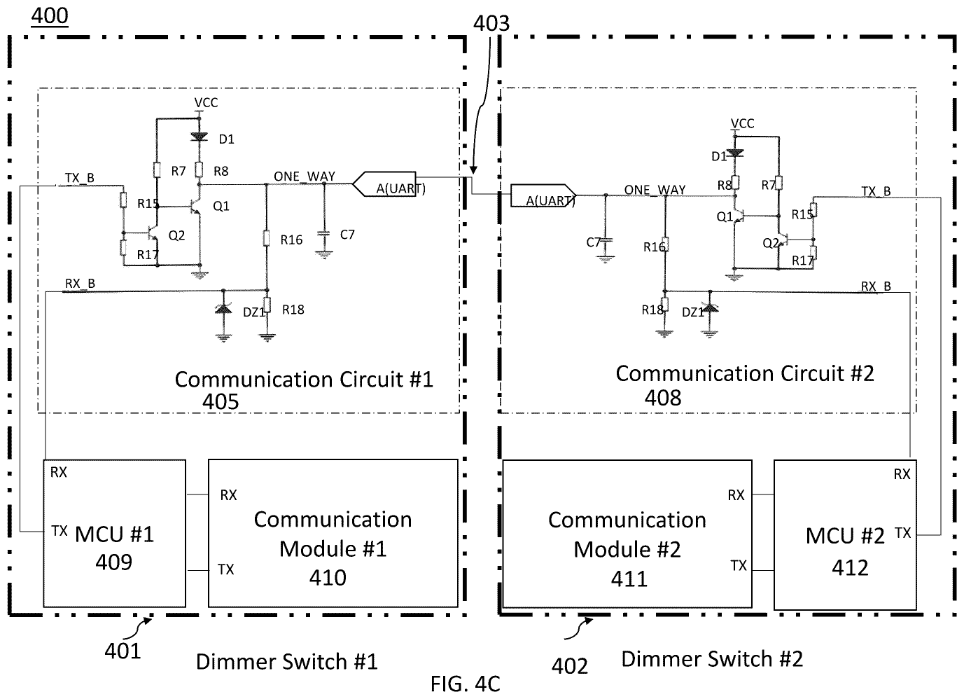

FIGS. 4A-4B illustrate an exemplary multi-dimmer system 400 according to embodiments of the present disclosure. In the exemplary embodiment 400 of FIGS. 4A4B, a first dimmer switch/assembly 401 is electrically coupled to a second dimmer switch/assembly 402 by way of a single wire/connection, A (UART) 403. That is, the first dimmer switch/assembly 401 has a direct electrical coupling (e.g., via A (UART) 403) with the second dimmer switch/assembly 402. The first dimmer switch/assembly 401 is electrically coupled between a “hot” line 406A from voltage source 406 (e.g., AC 120V, 60 Hz) and a “neutral” line 406B from voltage source 406. The first dimmer switch/assembly 401 is also electrically coupled to ground 407. An output 401A of the first dimmer switch/assembly 401 remains unused. Further in the exemplary embodiment of FIGS. 4A-4B, thee second dimmer switch/assembly 402 is electrically coupled with a “hot” line 406A from voltage source 406 and a lighting or other load 404 via an output 402A of the second dimmer switch/assembly 402. The second dimmer switch/assembly 402 is also electrically coupled to ground 407. The lighting or other load 404 is also electrically coupled with the “neutral” line 406B from voltage source 406.

FIG. 4C illustrates interconnection communication within an exemplary multi-dimmer system 400 according to embodiments of the present disclosure. In embodiments, a first dimmer switch/assembly comprises a communication circuit 405, an MCU 409, and a communication module 410. In embodiments, a second dimmer switch/assembly comprises a communication circuit 408, a communication module 411, and an MCU 412. In embodiments, bidirectional communication occurs between the first dimmer switch/assembly 401 and the second dimmer switch/assembly 402 by way of a connection 403 (i.e., A (UART)). The bidirectional communication comprises transmitting and receiving data.

In embodiments, a mutual communication condition may in place whereby when a TX_B of the first dimmer switch/assembly 401 transmits data, the TX_B of the second dimmer switch/assembly 402 does not transmit data and its RX_B only receives data. Similarly, when a TX B of the second dimmer switch/assembly 402 transmits data, the TX_B of the first dimmer switch/assembly 401 does not transmits and its RX_B only receives data.

In embodiments, one of the first dimmer switch/assembly 401 or the second dimmer switch/assembly 402 acts as a master, and the other acts as a slave. The master/slave decisions are determined by an order of actuations of buttons on each of the assemblies 401, 402 (see below). If an RX B on either of the switches/assemblies 401, 402 does not receive any communication data, its MCU will detect its RX_B and TX_B as I/O ports. If the detected level on RX B continues for a certain duration of time (e.g., 300 ms), the MCU determines that the dimmer switch/assembly 401, 402 has an external driver (i.e., an external switch) and operations according to FIGS. 3A-3C ensue. If a continuous duration of a high-low level flip is not detected and no communication data is detected, the MCU determines that the dimmer/switch assembly 401, 402 is a single or solo dimmer.

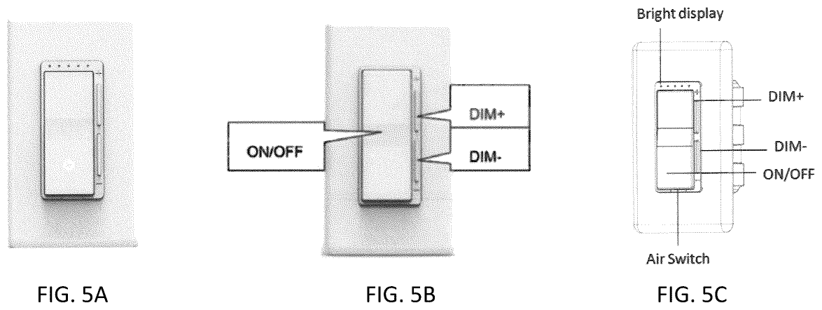

FIGS. 5A-5C illustrate various front views of an exemplary dimmer assembly for use with embodiments of the present disclosure. Shown in FIGS. 5A-5C, an exemplary dimmer assembly comprises a display area for an indication of brightness (“Bright display”), an actuatable area for increasing dimming (“DIM+”), an actuatable area for decreasing dimming (“DIM-”), an actuatable switch (“ON/OFF”) for turning the light switch ON or OFF, and a movable or actuatable air switch (“Air Switch”) that can be used to disable dimming capability (i.e., the light switch returns to normal functionality of ON/OFF only).

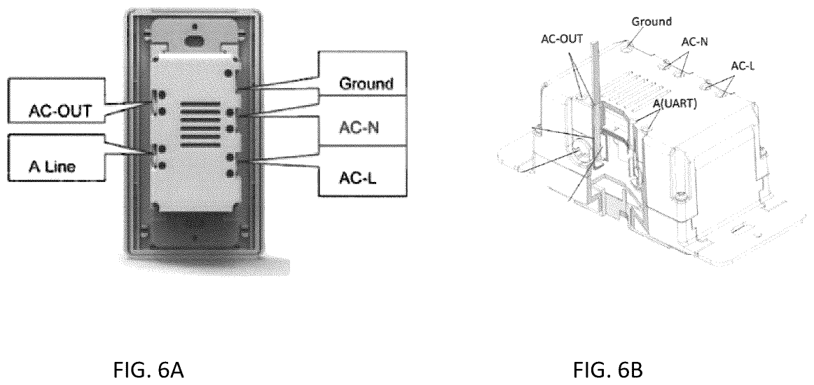

FIGS. 6A-6B illustrate rear views of an exemplary dimmer assembly for use with embodiments of the present disclosure. Shown in FIGS. 6A-6B, an exemplary dimmer assembly comprises a plurality of connectors or connection holes on the rear of the assembly. In embodiments, the plurality of connectors comprises a connector for ground (“Ground”), two connectors for AC-N (“AC-N”), two connectors for AC-L (“AC-L”), two connectors for AC-OUT (“AC-OUT”) and two connectors for the A communication line (“A Line” or “A (UART)”).

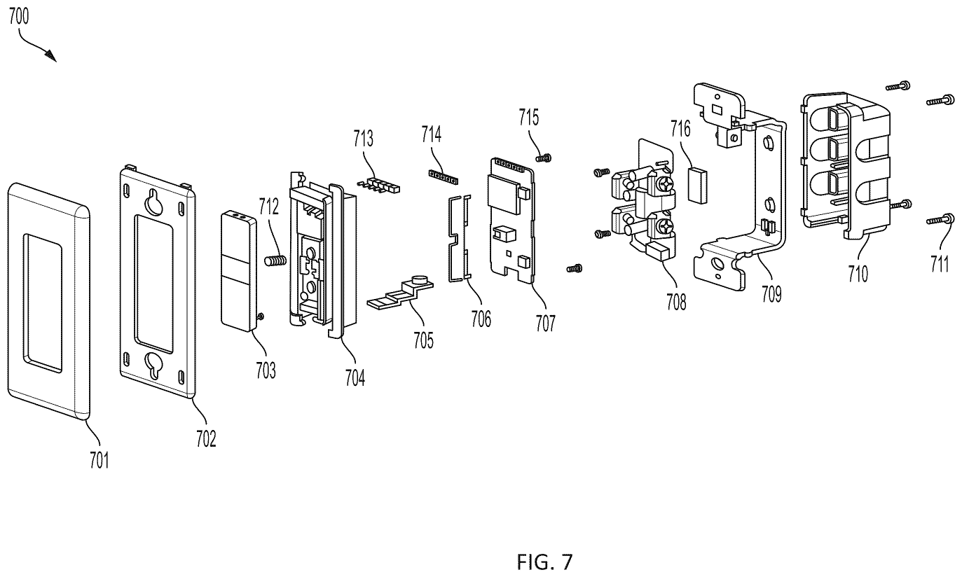

FIG. 7 illustrates an exploded view of an exemplary dimmer assembly 700 for use with embodiments of the present disclosure. In embodiments, dimmer assembly 700 comprises a face plate 701. In embodiments, the face plate 701 is connectable to a mounting frame 702. In embodiments, the mounting frame 702 comprises a button 703 that is connectable to an upper case 704 via a spring 712. The upper case 704 comprises an air button 705 and a light pipe 713. EVE foam 714 and a dimmer button 716 are situated between the upper case 704 and a PCB-A 707. A PCB-B 708 is attachable to the PCB-A 707 using screws 715. Thermal conductive silicone 716 is situated between the PCB-B 708 and an aluminum plate 709, that is situated in a bottom case 710. The entire assembly 700 is secured together using screws 711.

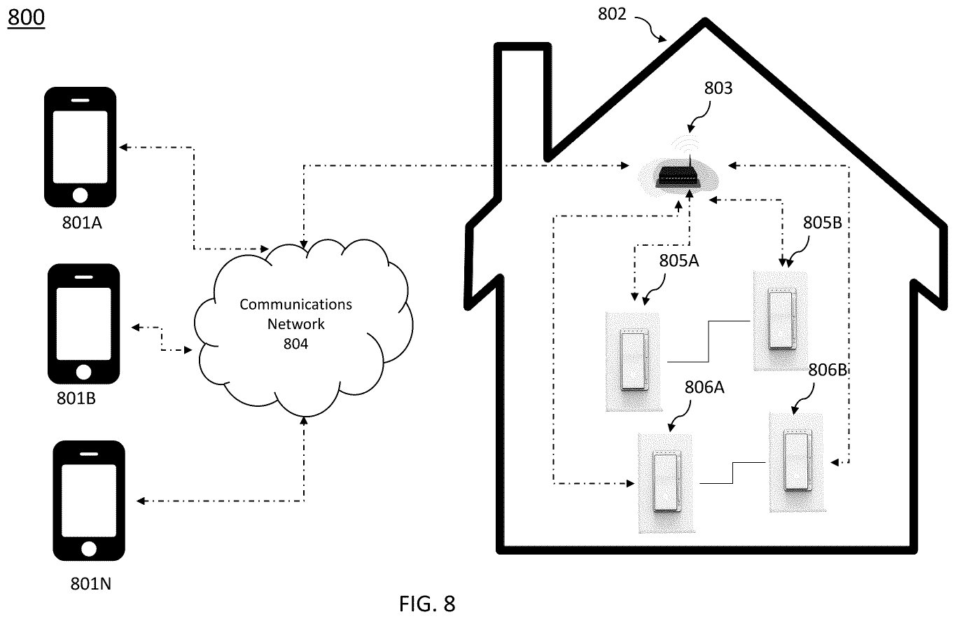

FIG. 8 illustrates an exemplary architecture 800 within which embodiments of the present disclosure may operate. In embodiments, an exemplary architecture 800 comprises one or more exemplary dimmer switch/assemblies 805A, 805B, 806A, 806B that are communicably coupled with a router 803. One or more client devices (also referred to herein as computing devices or remote computing devices) 801A-801N may access the one or more exemplary dimmer switch/assemblies 805A, 805B, 806A, 806B by way of communications network 804 and through router 803. The one or more exemplary dimmer switch/assemblies 805A, 805B, 806A, 806B may be situated within a structure 802. Structure 802 may comprise a residence, a commercial building, and the like without departing from the scope of the present disclosure.

Client devices may include, without limitation, smart phones, tablet computers, laptop computers, wearables, personal computers, and the like.

In FIG. 8, communicable coupling that is achieved in a wireless or indirect manner is represented using dashed arrows. Also in FIG. 8, communicable or electrical coupling that is achieved in a direct manner is represented using solid lines. That is, exemplary dimmer switch/assembly 805A is in direct electrical communication (e.g., by way of a wired connection) with exemplary dimmer switch/assembly 805B, and exemplary dimmer switch/assembly 806A is in direct electrical communication (e.g., by way of a wired connection) with exemplary dimmer switch/assembly 806B.

Communications network 804 may include any wired or wireless communication network including, for example, a wired or wireless local area network (LAN), personal area network (PAN), metropolitan area network (MAN), wide area network (WAN), or the like, as well as any hardware, software and/or firmware required to implement it (such as, e.g., network routers, router 803, etc.). For example, communications network 804 may include a cellular telephone, an 802.11, 802.16, 802.20, and/or WiMax network. Further, the communications network 804 may include a public network, such as the Internet, a private network, such as an intranet, or combinations thereof, and may utilize a variety of networking protocols now available or later developed including, but not limited to TCP/IP based networking protocols. For instance, the networking protocol may be customized to suit the needs of the multi-dimmer system. In some embodiments, the protocol is a custom protocol of JSON objects sent via a Websocket channel. In some embodiments, the protocol is JSON over RPC, JSON over REST/HTTP, and the like.

In embodiments where a client device 801A-801N is a mobile device, such as a smart phone or tablet, the client device 801A-801N may execute an “app” to interact with the multi-dimmer/switch system. Such apps are typically designed to execute on mobile devices, such as tablets or smartphones. For example, an app may be provided that executes on mobile device operating systems such as iOS®, Android®, or Windows®. These platforms typically provide frameworks that allow apps to communicate with one another and with particular hardware and software components of mobile devices. For example, the mobile operating systems named above each provide frameworks for interacting with location services circuitry, wired and wireless network interfaces, user contacts, and other applications. Communication with hardware and software modules executing outside of the app is typically provided via application programming interfaces (APIs) provided by the mobile device operating system.

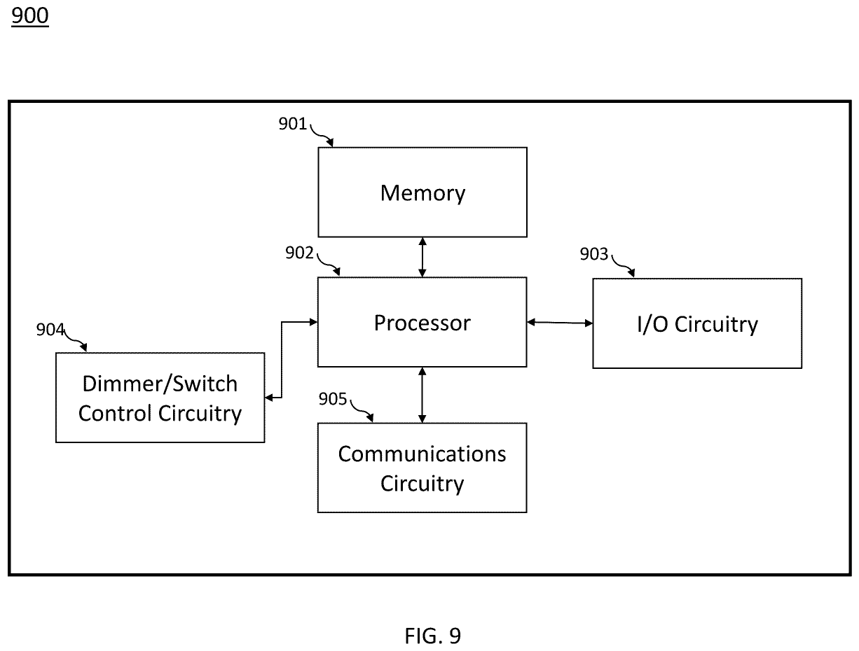

FIG. 9 illustrates an exemplary apparatus for use with embodiments of the present disclosure. A client device 801A-801N may be embodied by one or more computing systems, such as apparatus 900 shown in FIG. 9. The apparatus 900 may include a processor 902, a memory 901, input/output circuitry 903, communications circuitry 905, and dimmer switch/assembly control circuitry 904. The apparatus 900 may be configured to execute the operations described herein. Although the components are described with respect to functional limitations, it should be understood that the particular implementations necessarily include the use of particular hardware. It should also be understood that certain of the components described herein may include similar or common hardware. For example, two sets of circuitry may both leverage use of the same processor, network interface, storage medium, or the like to perform their associated functions, such that duplicate hardware is not required for each set of circuitry. The use of the term “circuitry” as used herein with respect to components of the apparatus should therefore be understood to include particular hardware configured to perform the functions associated with the particular circuitry as described herein.
[1] The term “circuitry” should be understood broadly to include hardware and, in some embodiments, software for configuring the hardware. For example, in some embodiments, “circuitry” may include processing circuitry, storage media, network interfaces, input/output devices, and the like. In some embodiments, other elements of the apparatus 900 may provide or supplement the functionality of particular circuitry. For example, the processor 902 may provide processing functionality, the memory 901 may provide storage functionality, the communications circuitry 905 may provide network interface functionality, and the like.
[2] In some embodiments, the processor 902 (and/or co-processor or any other processing circuitry assisting or otherwise associated with the processor) may be in communication with the memory 901 via a bus for passing information among components of the apparatus. The memory 901 may be non-transitory and may include, for example, one or more volatile and/or non-volatile memories. In other words, for example, the memory may be an electronic storage device (e.g., a computer readable storage medium). The memory 901 may be configured to store information, data, content, applications, instructions, or the like, for enabling the apparatus to carry out various functions in accordance with example embodiments of the present disclosure.
[3] The processor 902 may be embodied in a number of different ways and may, for example, include one or more processing devices configured to perform independently. Additionally or alternatively, the processor may include one or more processors configured in tandem via a bus to enable independent execution of instructions, pipelining, and/or multithreading. The use of the term “processing circuitry” may be understood to include a single core processor, a multi-core processor, multiple processors internal to the apparatus, and/or remote or “cloud” processors.
[4] In an example embodiment, the processor 902 may be configured to execute instructions stored in the memory 901 or otherwise accessible to the processor. Alternatively, or additionally, the processor may be configured to execute hard-coded functionality. As such, whether configured by hardware or software methods, or by a combination thereof, the processor may represent an entity (e.g., physically embodied in circuitry) capable of performing operations according to an embodiment of the present disclosure while configured accordingly. Alternatively, as another example, when the processor is embodied as an executor of software instructions, the instructions may specifically configure the processor to perform the algorithms and/or operations described herein when the instructions are executed.
[5] In some embodiments, the apparatus 900 may include input/output circuitry 903 that may, in turn, be in communication with processor 902 to provide output to the user and, in some embodiments, to receive an indication of a user input. The input/output circuitry 903 may comprise a user interface and may include a display and may comprise a web user interface, a mobile application, a client device, a kiosk, or the like. In some embodiments, the input/output circuitry 903 may also include a keyboard, a mouse, a joystick, a touch screen, touch areas, soft keys, a microphone, a speaker, or other input/output mechanisms. The processor and/or user interface circuitry comprising the processor may be configured to control one or more functions of one or more user interface elements through computer program instructions (e.g., software and/or firmware) stored on a memory accessible to the processor (e.g., memory 901, and/or the like).
[6] The communications circuitry 905 may be any means such as a device or circuitry embodied in either hardware or a combination of hardware and software that is configured to receive and/or transmit data from/to a network and/or any other device, circuitry, or module in communication with the apparatus 900. In this regard, the communications circuitry 905 may include, for example, a network interface for enabling communications with a wired or wireless communication network. For example, the communications circuitry 905 may include one or more network interface cards, antennae, buses, switches, routers, modems, and supporting hardware and/or software, or any other device suitable for enabling communications via a network. Additionally or alternatively, the communication interface may include the circuitry for interacting with the antenna(s) to cause transmission of signals via the antenna(s) or to handle receipt of signals received via the antenna(s).
[7] The dimmer switch/assembly control circuitry 904 includes hardware configured to control a single or multi-dimmer switch system. The dimmer switch/assembly control circuitry 904 may utilize processing circuitry, such as the processor 902, to perform these actions. It should also be appreciated that, in some embodiments, the dimmer switch/assembly control circuitry 904 may include a separate processor, specially configured field programmable gate array (FPGA), or application specific interface circuit (ASIC).

The foregoing Detailed Description signifies in isolation the individual features, structures, functions, or characteristics described herein and any combination of two or more such features, structures, functions or characteristics, to the extent that such features, structures, functions or characteristics or combinations thereof are based on the present specification as a whole in light of the knowledge of a person skilled in the art, irrespective of whether such features, structures, functions or characteristics, or combinations thereof, solve any problems disclosed herein, and without limitation to the scope of the claims. When an embodiment of a claimed invention comprises a particular feature, structure, function or characteristic, it is within the knowledge of a person skilled in the art to use such feature, structure, function, or characteristic in connection with other embodiments whether or not explicitly described, for example, as a substitute for another feature, structure, function or characteristic.

In view of the foregoing Detailed Description it will be evident to a person skilled in the art that many variations may be made within the scope of innovations, embodiments and/or examples, such as function and arrangement of elements, described herein without departing from the principles described herein. One or more elements of an embodiment may be substituted for one or more elements in another embodiment, as will be apparent to those skilled in the art. The embodiments described herein are chosen to signify the principles of the invention and its useful application, thereby enabling others skilled in the art to understand how various embodiments and variations are suited to the particular uses signified.

The foregoing Detailed Description of innovations, embodiments, and/or examples of the claimed inventions has been provided for the purposes of illustration and description. It is not intended to be exhaustive nor to limit the claimed inventions to the precise forms described, but is to be accorded the widest scope consistent with the principles and features disclosed herein. Obviously, many variations will be recognized by a person skilled in this art. Without limitation, any and all equivalents described, signified or incorporated by reference in this patent application are specifically incorporated by reference into the description herein of the innovations, embodiments and/or examples. In addition, any and all variations described, signified or incorporated by reference herein with respect to any one embodiment are also to be considered taught with respect to all other embodiments. Any such variations include both currently known variations as well as future variations, for example any element used herein includes a future equivalent element that provides the same function, regardless of the structure of the future equivalent.

It is intended that the scope of the claimed inventions be defined and judged by the following claims and equivalents. The following claims are hereby incorporated into the Detailed Description, with each claim standing on its own as a separate embodiment. Disclosed embodiments can be described with more features than are expressly recited in the claims.

What is claimed is:

1. A multi-dimmer system, comprising:
a first dimmer assembly electrically coupled to a second dimmer assembly via a physical data transmission line,
wherein the first dimmer assembly receives dimming instructions via one or more of a first actuatable physical switch or a communications module in communication with one or more remote computing devices, and
wherein the first dimmer assembly acts as a master device and the second dimmer assembly acts as a slave device such that dimming instructions carried out by the first dimmer assembly are propagated via the data transmission line to the second dimmer assembly.

2. The multi-dimmer system of claim 1, wherein the physical data transmission line is a single electrical wire.

3. The multi-dimmer system of claim 1, wherein the first dimmer assembly is electrically couplable to a “hot” line of a voltage source, and ground.

4. The multi-dimmer system of claim 3, wherein the first dimmer assembly is also electrically couplable to a “neutral” line of the voltage source.

5. The multi-dimmer system of claim 3, wherein an output of the first dimmer assembly remains floating.

6. The multi-dimmer system of claim 1, wherein the second dimmer assembly is electrically couplable with a “hot” line of a voltage source, a lighting or other load, and ground, wherein the second dimmer assembly is electrically couplable with the lighting or other load via an output of the second dimmer assembly.

7. The multi-dimmer system of claim 6, wherein the lighting or other load is electrically couplable with a “neutral” line of the voltage source.

8. The multi-dimmer system of claim 1, wherein each of the first dimmer assembly and the second dimmer assembly comprises an MCU, a communication circuit, and a communications module.

9. The multi-dimmer system of claim 8, wherein the communication circuit comprises a transmission port TX_B coupled to an MCU data transmission port, and wherein the communication circuit comprises a receiving port RX_B coupled to an MCU data receiving port.

10. The multi-dimmer system of claim 9, wherein a waveform of the data transmission line follows a signal waveform of the transmission port TX_B.

11. The multi-dimmer system of claim 9, wherein when a TX_B of the first dimmer assembly transmits data, a TX_B of the second dimmer assembly does not transmit data.

12. The multi-dimmer system of claim 11, wherein when the TX_B of the second dimmer assembly transmits data, the TX_B of the first dimmer assembly does not transmit data.

13. The multi-dimmer system of claim 8, wherein the communications module enables communication via a wireless communications network with a remote computing device.

14. The multi-dimmer system of claim 1, further comprising:
a third dimmer assembly electrically coupled to a fourth dimmer assembly via a second physical data transmission line.

15. The multi-dimmer system of claim 14, wherein the third dimmer assembly receives dimming instructions via one or more of the first actuatable physical switch, a second actuatable physical switch, or a second communications module in communication with one or more remote computing devices.

16. The multi-dimmer system of claim 15, wherein the third dimmer assembly acts as a master device and the fourth dimmer assembly acts as a slave device such that dimming instructions carried out by the third dimmer assembly are propagated via the second data transmission line to the fourth dimmer assembly.

17. A dimmer system, comprising:
a first dimmer assembly electrically coupled to a standard three-way switch via a physical data transmission line,
wherein the first dimmer assembly receives dimming instructions via one or more of an actuatable physical switch or a communications module in communication with a remote computing device, and
wherein instructions carried out by the first dimmer assembly are propagated via the data transmission line to the standard three-way switch.
